(19) United States
(12) Patent Application Publication
(10) Pub. No.: US 2026/0133242 A1
(43) Pub. Date: May 14, 2026

(54) APPARATUS FOR CHECKING BATTERY AND CHECKING METHOD OF BATTERY

(71) Applicant: SK On Co., Ltd., Seoul (KR)

(72) Inventors: Hye Ju JANG, Daejeon (KR); Dong Min JEONG, Daejeon (KR)

(21) Appl. No.: 19/386,228

(22) Filed: Nov. 12, 2025

(30) Foreign Application Priority Data
Nov. 12, 2024 (KR) 10-2024-0160334

(51) Int. Cl. G01R 31/14; G01R 31/12; H01M 10/42; H01M 50/105

(52) U.S. Cl. CPC G01R 31/14; G01R 31/1263; H01M 10/4285; H01M 50/105

(57) ABSTRACT

The present disclosure relates to an apparatus for checking battery. The apparatus for checking battery may comprise: a working unit that contacts a conductive elastic member to a casing of a battery to be checked; and a measuring unit that applies a voltage between the casing and the conductive elastic member, measures a resistance value, and determines whether the casing is insulated based on the resistance value.

### CROSS-REFERENCE TO RELATED PATENT APPLICATION

The present application claims priority under 35 U.S.C. § 119a to Korean patent application number 10-2024-0160334 filed on Nov. 12, 2024, in the Korean Intellectual Property Office, the entire disclosure of which is incorporated by reference herein.

### BACKGROUND OF THE DISCLOSURE

### 1. Field

This disclosure relates to an apparatus for checking a battery and a method for checking a battery, specifically an apparatus and method for quickly and accurately checking whether a battery is insulated.

### 2. Description of the Related Art

A secondary battery is a battery that converts electrical energy into chemical energy for storage, enabling reuse multiple times through charging and discharging. Due to their economical and eco-friendly characteristics, secondary batteries are used diversely and extensively across various industries. Among secondary batteries, lithium secondary batteries (Lithium Secondary Battery) are widely utilized across industries, including portable devices requiring high-density energy.

Secondary batteries can be categorized by their unit into battery cells and battery assemblies (e.g., battery modules, battery packs). A battery module may contain multiple battery cells, and a battery pack may contain multiple battery modules.

Defects in secondary batteries can occur during the manufacturing process due to various causes, such as physical impact from external sources or manufacturing process defects. Such defects in secondary batteries can lead to problems like explosions and fires. Therefore, technology for checking defects in secondary batteries is required.

One embodiment of the present disclosure provides a battery checking apparatus and a battery checking method.

One embodiment of the present disclosure provides a battery checking apparatus and a battery checking method capable of quickly and accurately checking the insulation properties of a battery.

One embodiment of the present disclosure provides a battery checking apparatus and a battery checking method capable of checking the insulation of a battery cell.

Meanwhile, the battery checking apparatus and battery checking method according to this disclosure can be widely applied in the fields of green technology, such as electric vehicles (EV), battery charging stations, energy storage systems (ESS), and other battery-utilizing technologies like photovoltaics and wind power. Furthermore, the battery checking apparatus and battery checking method according to this disclosure can be used in eco-friendly mobility, including electric vehicles and hybrid vehicles, to prevent climate change by suppressing air pollution and greenhouse gas emissions.

### SUMMARY OF THE DISCLOSURE

An apparatus for checking battery according to one embodiment of the present disclosure may comprise: a working unit that contacts a conductive elastic member to a casing of a battery to be checked; and a measuring unit that applies a voltage between the casing and the conductive elastic member, measures a resistance value, and determines whether the casing is insulated based on the resistance value.

In an embodiment, the working unit may include a work table and the conductive elastic member provided on the work table.

In an embodiment, the apparatus for checking battery may further comprise: a pressing unit including a pressing jig that presses the conductive elastic member and contacts the conductive elastic member to the casing.

In an embodiment, the battery to be checked may be moved in a horizontal direction, and the pressing jig may move from top to bottom to contact with the casing.

In an embodiment, the conductive elastic member may cover the entire surface of one side of the casing.

In an embodiment, the measuring unit may measure the resistance value and include a resistance measuring device including first and second terminals electrically connected to the casing and the conductive elastic member.

In an embodiment, the conductive elastic member may be disposed on one side and another side of the casing, and the resistance measuring device may further include a third terminal, and the second terminal and the third terminal may be electrically connected to a conductive rubber disposed on the one side and another side of the casing.

In an embodiment, the battery to be checked may be a pouch-type battery cell.

In an embodiment, the casing may include a first insulating layer, a conductive layer, and a second insulating layer stacked together, and the conductive layer may be exposed on a side of the casing.

In an embodiment, the apparatus for checking battery may further comprise: a transfer unit for transferring the battery to be checked to the working unit.

In an embodiment, the battery to be checked may be moved in the working unit with or without stopping for a predetermined period of time.

A checking method of battery according to another embodiment of the present disclosure may comprise: a step of contacting a conductive elastic member to a casing of a battery to be checked; and a step of applying a voltage between the casing and the conductive elastic member, measuring a resistance value, and determining whether the casing is insulated based on the resistance value.

In another embodiment, the battery to be checked may be moved in a horizontal direction, and the conductive elastic member may move from top to bottom to contact with the casing with a predetermined pressure.

In another embodiment, the casing may include a first insulating layer, a conductive layer, and a second insulating layer stacked together, and the resistance value may be measured between the conductive layer and the conductive elastic member.

In another embodiment, the conductive elastic member may cover the entire surface of one side of the casing.

According to one embodiment of the present disclosure, the insulating property of the battery casing can be checked quickly and accurately.

According to one embodiment of the present disclosure, the insulating property of a battery cell can be quickly and accurately checked.

According to one embodiment of the present disclosure, the insulating property of a pouch-type battery cell can be quickly and accurately checked.

According to one embodiment of the present disclosure, the insulating property of the pouch outer casing of a battery cell can be quickly and accurately checked.

### BRIEF DESCRIPTION OF THE DRAWINGS

FIG. 1 is a block diagram illustrating an apparatus for checking battery according to one embodiment.

FIGS. 2 and 3 are diagrams showing the battery checking process according to one embodiment.

FIG. 4 is a cross-sectional view schematically illustrating a battery cell according to one embodiment.

FIG. 5 is a diagram schematically illustrating a method for manufacturing a pouch-type battery cell according to one embodiment.

FIG. 6 is a schematic drawing illustrating a portion of a state in which an electrode assembly is accommodated in a pouch sheet according to one embodiment.

FIG. 7 is a diagram illustrating a method for determining whether a casing is insulated.

FIG. 8 is a diagram illustrating a method for determining whether a casing is insulated according to one embodiment.

FIGS. 9 and 10 are schematic diagrams illustrating samples for validating the effectiveness of the present disclosure.

FIG. 11 is a schematic diagram illustrating a resistance value measurement method for a battery cell according to one embodiment.

### DETAILED DESCRIPTION

Hereinafter, the present disclosure will be described in detail with reference to the accompanying drawings. However, this is merely illustrative, and the present disclosure is not limited to the specific embodiments described by way of example.

The structural or functional descriptions of the embodiments disclosed in this specification or application are merely exemplified for the purpose of explaining embodiments according to the technical concept of the present disclosure. Embodiments according to the technical idea of the present disclosure may be implemented in various forms other than the embodiments disclosed in this specification or application, and the technical idea of the present disclosure is not construed as being limited to the embodiments described in this specification or application.

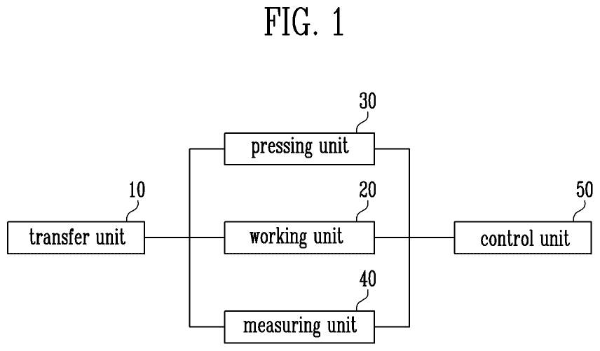

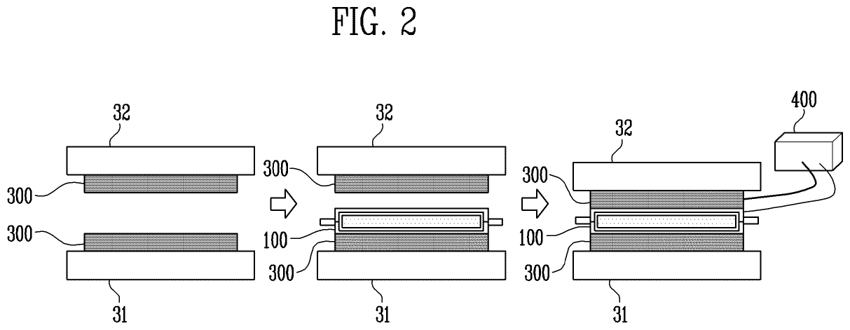

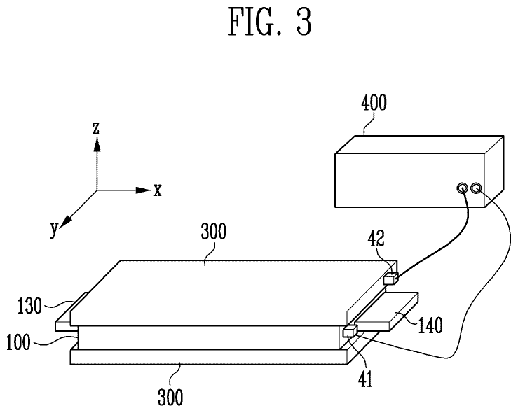

FIG. 1 is a block diagram illustrating an apparatus for checking battery according to one embodiment. FIGS. 2 and 3 are diagrams showing the battery checking process according to one embodiment.

Referring to FIGS. 1 to 3, the apparatus for checking battery may comprise a working unit 20 that contacts a conductive elastic member to a casing of a battery to be checked; and a measuring unit 40 that applies a voltage between the casing and the conductive elastic member, measures a resistance value, and determines whether the casing is insulated based on the resistance value.

The battery checking apparatus according to one embodiment of the present disclosure may be for checking the insulation of a battery.

According to one embodiment, the battery checking apparatus may check whether the insulating layer of the battery casing is damaged.

According to one embodiment, the battery checking apparatus may check whether the conductor layer of the battery casing is exposed.

In one embodiment, the battery checking apparatus may be used to check the insulation of a battery cell. Whether the insulation of a battery cell is maintained is an important criterion for determining battery cell defects, and may be measured during the battery cell manufacturing stage. Furthermore, without being limited thereto, it may be used in environments where battery insulation measurement is required, such as during battery use.

In one embodiment, the battery being tested by the battery checking apparatus may be a rechargeable battery capable of multiple charge and discharge cycles. The rechargeable battery is not limited to this, but may include, for example, lithium cobalt batteries, lithium high-nickel batteries, lithium iron phosphate batteries, lithium-ion batteries, lithium polymer batteries, lithium sulfur batteries, nickel-metal hydride batteries, nickel-cadmium batteries, sodium batteries, and all-solid-state batteries.

In one embodiment, the battery checking apparatus may include a transfer unit 10 for transferring the battery to be checked to the working unit 20. The transfer unit 10 can move the battery in a specific direction. For example, the specific direction may be a horizontal direction.

In one embodiment, the transfer unit 10 may include a conveyor and a transfer motor. The transfer motor may transmit rotational force to the conveyor. When rotational force is transmitted, the conveyor may move a battery located at a specific point on the conveyor to another point.

In one embodiment, when the battery checking apparatus is used during the battery manufacturing stage, it may be used to measure the insulation properties of the battery cell during the quality checking stage after the assembly process of the battery cell is completed and the aging and degassing processes are finished. The following description is based on the battery cell 100, but the battery checking apparatus according to this disclosure may be used to check the insulation properties of various battery forms.

Battery cells 100 may be classified based on their packaging form, including but not limited to pouch-type, coin-type, cylindrical-type, or prismatic-type.

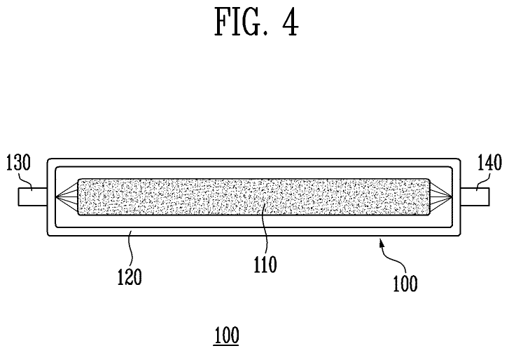

FIG. 4 is a cross-sectional view schematically illustrating a battery cell according to one embodiment.

In one embodiment, the battery cell 100 may be configured such that an electrode assembly 110 is housed within a battery casing 120.

The electrode assembly 110 may include multiple electrode layers and a separator disposed between the multiple electrode layers. The multiple electrode layers may include at least one negative electrode layer and at least one positive electrode layer.

In one embodiment, the battery cell 100 may further include an electrolyte. The electrolyte may include a material that functions as a medium facilitating the movement of ions, such as lithium ions.

In one embodiment, the working unit 20 may be provided with a conductive elastic member 300. At the working unit 20, the battery cell 100 may be in contact with the conductive elastic member 300.

The battery cell 100 may be transferred to the working unit 20 by the transfer section 10. In one embodiment, the working unit 20 may include a work table 31, and the work table 31 may be provided with a conductive elastic member 300. The battery cell 100 to be checked may be placed on the conductive elastic member 300 provided on the work table 31.

When the battery cell 100 moves to the working unit, it may stop for a predetermined time for checking. Alternatively, in one embodiment, the battery cell 100 may undergo checking while moving without stopping at the working unit.

In one embodiment, the conductive elastic member 300 may cover the entire surface of one side of the casing of the battery cell 100.

In one embodiment, the battery checking apparatus may further include a pressing unit 30 including a pressing jig 32 that presses the conductive elastic member and contacts the conductive elastic member to the casing.

For example, a pressing unit 30 may be further included to press the conductive elastic member into contact with the battery casing. The pressing unit 30 may include a pressing jig 32.

In one embodiment, as shown in FIG. 2, the conductive elastic member 300 may be contacted to the top surface of the battery cell 100 placed on the working unit 20. The conductive elastic member 300 may move from the top to the bottom via the pressing jig 32.

In one embodiment, the battery cell 100 can move in a horizontal direction, and the pressing jig 32 can move in a vertical direction (z-axis direction). The battery cell 100 to be checked moves horizontally, and the pressing jig 32 and the conductive elastic member 300 move from the top to the bottom to contact the battery cell 100. Upon completion of the checking, the pressing jig 32 and the conductive elastic member 300 can rise. The conductive elastic member 300 contacting the battery cell 100 via the pressing jig 32 allows the conductive elastic member 300 and the battery cell 100 to be pressed with appropriate pressure, thereby enhancing the accuracy of resistance measurement.

In one embodiment, both the front and back surfaces of the battery cell 100 can be checked simultaneously. Referring to FIG. 2, the conductive elastic member 300 provided on the work table 31 of the working unit 20 can contact one surface of the battery cell 100, and the conductive elastic member 300 provided by the pressing jig 32 can contact the other surface of the battery cell 100.

According to one embodiment, the conductive elastic member 300 possesses elasticity, allowing it to contact one surface of the battery cell 100 under a predetermined pressure applied by the pressing jig 32. Although not limited thereto, the conductive elastic member 300 may be a conductive rubber member. Due to the characteristics of rubber material, even when contacting as close as possible to the battery casing, damage to the battery casing can be minimized.

In one embodiment, the battery checking apparatus can be applied to a pouch-type battery cell 100. In one embodiment, the pouch-type battery cell 100 may include a folding portion 120F.

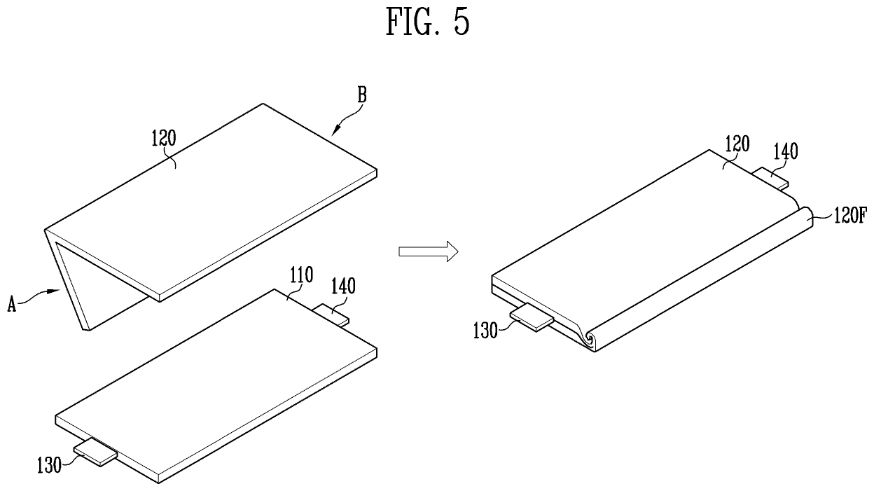

FIG. 5 is a diagram schematically illustrating a method for manufacturing a pouch-type battery cell according to one embodiment.

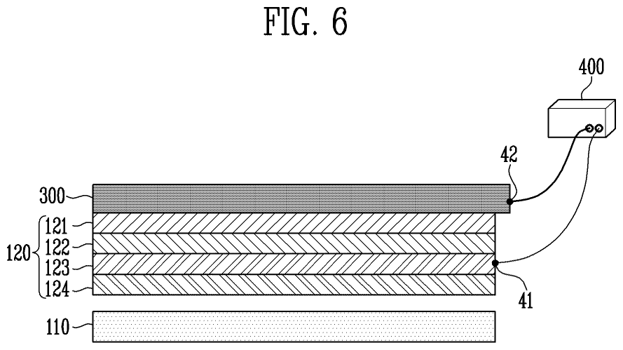

Referring to FIG. 5, a pouch casing 120 may be used as the battery casing. The pouch casing 120 may be a laminate comprising a first insulating layer 121, 122, a conductive layer 123, and a second insulating layer 124. This pouch casing 120 structure can be understood with reference to FIG. 6.

FIG. 6 is a schematic drawing illustrating a portion of a state in which an electrode assembly 110 is accommodated in a pouch sheet according to one embodiment.

In one embodiment, the electrode assembly 110 may be accommodated in the pouch sheet 120, the pouch sheet 120 may be sealed to seal the pouch sheet, and it may be folded to form a folding portion 120F. Without being limited thereto, for example, the electrode assembly 110 may be placed on the pouch sheet 120, the pouch sheet 120 may be folded in half, and the three sides excluding the folded portion may be sealed. Of the three sides, the folding portion 120F may be formed by folding one sealing side, excluding the two sides A, B where the electrode leads 130, 140 are exposed. In this case, both side ends of the pouch sheet may be exposed.

That is, in one embodiment, the electrode assembly 110 may include electrode leads 130, 140, and the electrode leads 130, 140 may be exposed at the sides A, B of the pouch sheet, i.e., the sides where the folding portion 120F is not formed among the three sealed sides. Accordingly, the conductive layer 123 of the pouch sheet may be exposed to the outside.

As shown in FIG. 6, the pouch casing 120 may include a first insulating layer 121, 122, a conductive layer 123, and a second insulating layer 124, and the pouch casing 120 may expose the conductive layer 123 on its side.

It may include a conductive layer 123 to maintain the shape of the battery cell and prevent moisture penetration, and an insulating layer may be formed on one side and another side of the conductive layer 123 to control the electrical characteristics of the battery cell.

Without limitation, for example, the pouch casing 120 may include a first insulating layer 121, 122, a conductive layer 123, and a second insulating layer 124.

The first insulating layer 121, 122 is formed on one surface of the conductive layer 123, preventing the top surface of the conductive layer 123 from being exposed externally. Without being limited thereto, for example, the first insulating layer 121, 122 may be formed from polyethylene terephthalate (PET) or nylon material. Without being limited thereto, for example, the first insulating layer 121, 122 may be formed with a thickness of 10 to 30 μm. The PET layer, formed at the outermost layer, can serve to block moisture and maintain surface rigidity. The nylon layer can be used to protect the battery cell from external impacts and to maintain insulation and heat resistance.

The conductive layer 123 may be formed from a metallic material, without limitation, for example, aluminum. Without limitation, the conductive layer 123 may be formed with a thickness of 30 to 50 μm.

The second insulating layer 124 may be formed on the other surface of the conductive layer 123 and may prevent the electrode assembly from contacting the conductive layer 123. Without limitation, the second insulating layer 124 may be formed from a material such as polypropylene (PP). Without being limited thereto, for example, the second insulating layer 124 may be formed with a thickness of 50 to 100 μm. The PP layer has excellent formability and heat-sealing property and can be used for heat resistance, water resistance, and electrolyte resistance.

Referring to FIG. 6, in one embodiment, when a conductive elastic member 300 contacts the battery cell 100, a voltage is applied between the pouch casing 120 and the conductive elastic member 300 by the measuring unit 40, and the resistance value between the pouch casing 120 and the conductive elastic member 300 can be measured.

In one embodiment, the measuring unit 40 may measure the resistance value and include a resistance measuring device 400 including first and second terminals 41, 42 electrically connected to the casing 120 and the conductive elastic member 300.

For example, the measuring unit 40 may include a resistance measuring device 400. The resistance measuring device 400 may include first and second terminals 41, 42 and a voltage may be applied to the pouch casing 120 and the conductive elastic member 300 through the resistance measuring device 400, and the resistance value between them may be measured. In one embodiment, the first terminal 41 of the resistance measuring device 400 may be electrically connected to the pouch casing 120, and the second terminal 42 may be electrically connected to the conductive elastic member 300. After contacting the conductive elastic member 300 with the pouch casing 120, a voltage can be applied and the resistance value between them can be measured.

In one embodiment, the insulation status of the pouch casing can be determined based on the measured resistance value.

If the insulating layer in the pouch casing is undamaged, i.e., if one side of the conductive layer 123 of the pouch casing is covered by the insulating layer, no current flows between the conductive elastic member 300 and the pouch casing, resulting in a high resistance value. Conversely, if the insulating layer of the pouch casing is damaged, exposing the conductive layer through the insulating layer, current flows between the conductive elastic member 300 and the conductive layer 123 of the pouch casing, resulting in a low resistance value.

Therefore, a high resistance value indicates that the pouch casing's insulation has not been damaged, while a low resistance value indicates that the pouch casing's insulation has been damaged.

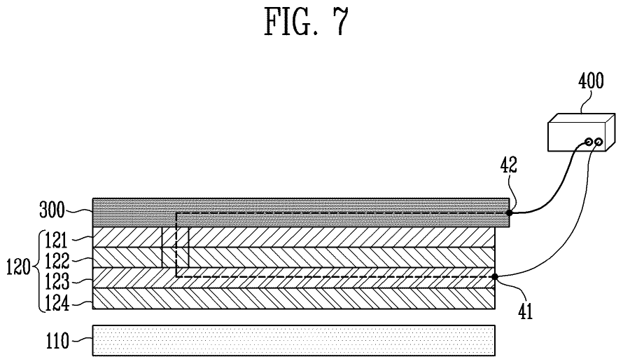

FIG. 7 is a diagram illustrating a method for determining whether a casing is insulated.

As shown in FIG. 6, in one embodiment, the first terminal 41 may be connected to the conductive layer 123 of the pouch casing.

In one embodiment, the pouch casing 120 may have a conductive layer 123 exposed on its side. Specifically, as shown in FIG. 5, the conductive layer 123 may be exposed on the side of the pouch casing where no folding portion 120F is formed. A first terminal 41 may be electrically connected to the conductive layer 123, and a second terminal 42 may be electrically connected to a conductive elastic member 300 placed on the top surface of the first insulating layer 121, 122. A voltage can be applied to the conductive layer 123 and the conductive elastic member 300, and the resistance value can be measured.

As shown in FIG. 6, when the conductive layer 123 is not exposed to the first insulating layer 121, 122 of the pouch casing in contact with the conductive elastic member 300, no current flows between the conductive elastic member 300 and the pouch casing 120, allowing it to exhibit a high resistance value.

Conversely, as shown in FIG. 7, if the conductive layer 123 is exposed on the surface of the pouch casing 120, current can flow between the conductive elastic member 300 and the conductive layer 123, resulting in a low resistance value. If the measured resistance value is low as described, it can be judged that the insulation of the pouch casing has been compromised.

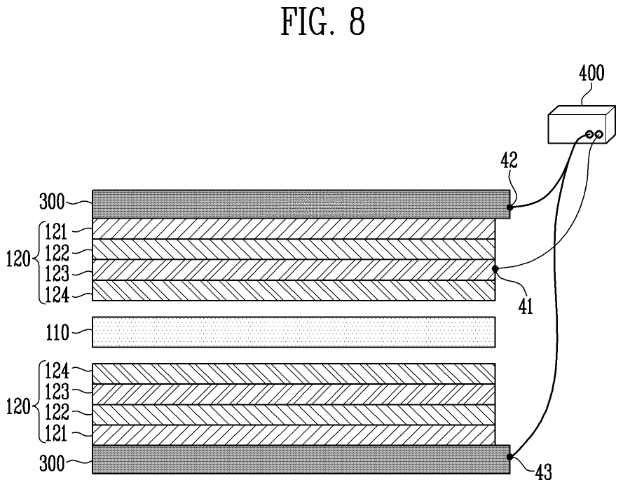

FIG. 8 is a diagram illustrating a method for determining whether a casing is insulated according to one embodiment.

In one embodiment, the conductive elastic member 300 may be disposed on one side and another side of the casing 120, and the resistance measuring device 400 may further include a third terminal 43, and the second terminal 42 and the third terminal 43 are electrically connected to a conductive rubber disposed on the one side and another side of the casing 120.

For example, the resistance measuring device 400 may include a third terminal 43. The first terminal 41 of the resistance measuring device 400 is electrically connected to the conductive layer 123 of the pouch casing, and the second terminal 42 and third terminal 43 can be electrically connected to the conductive elastic member 300 placed on the top surface and bottom surface of the pouch casing, respectively. A voltage can be applied to the conductive elastic member 300 in contact with the pouch casing 120, and the resistance value between them can be measured. In this case, both surfaces of the pouch casing 120 can be checked simultaneously. The pouch outer material 120 is a single pouch sheet, and if the first insulating layer 121, 122 is damaged on one side or the other side of the pouch casing 120 and the conductor layer 123 is exposed, the resistance value may decrease.

In one embodiment, the battery checking apparatus may include a control unit 50. The control unit 50 can control the overall operation of the battery checking apparatus.

In one embodiment, the control unit 50 can control the operation of at least one of the transfer unit 10, the working unit 20, the pressure unit 30, or the measurement unit 40.

Upon completion of the insulation checking on the battery cell, the battery cell may be moved to another location by the transfer unit 10.

As described above, in one embodiment, when the battery cell 100 moves to the working unit 20, it may stop for a predetermined time for checking, or checking may proceed while moving without stopping at the working unit 20.

According to one embodiment, since the checking is performed by contacting the conductive elastic member with the battery cell, the checking time is not long. Therefore, the checking can proceed while the battery is moving without stopping the battery to be checked at the work section. Accordingly, battery checking can be performed while keeping pace with battery mass production speed.

The battery checking method according to one embodiment of the present disclosure may include: a step of contacting a conductive elastic member to a casing of a battery to be checked; and a step of applying a voltage between the casing and the conductive elastic member, measuring a resistance value, and determining whether the casing is insulated based on the resistance value.

The battery checking method according to one embodiment of the present disclosure may use the aforementioned battery checking apparatus.

According to one embodiment, the battery cell 100 to be checked can first be transferred to the working unit 20. Without being limited thereto, for example, the battery cell 100 to be checked can be transferred in a horizontal direction.

As shown in FIG. 2, once the battery to be checked is positioned on the working unit 20, a conductive elastic member 300 can be brought into contact with the battery casing.

In one embodiment, when the battery moves to the working unit 20, it may stop for a predetermined time for checking, or the battery may not stop at the working unit 20 and checking may proceed while moving.

In one embodiment, the battery to be checked may be a pouch-type battery cell 100.

In one embodiment, the working unit 20 may include a work table 31, and the work table may be equipped with a conductive elastic member 300. The battery cell 100 may be placed on the conductive elastic member 300.

Furthermore, in one embodiment, the battery checking apparatus may include a pressing unit 30, and the pressing unit 30 may include a pressing jig 32. The pressing jig 32 may be provided with a conductive elastic member 300. The pressing jig 32 may move from the upper to the lower direction.

In one embodiment, the battery cell 100 may move in a horizontal direction, and the pressing jig 32 and the conductive elastic member 300 may move from the top to the bottom (z-axis direction) and contact the battery cell 100 with a predetermined pressure. Upon completion of the checking, the pressing jig 32 and the conductive elastic member 300 can rise.

The movement direction of the pressing jig 32 and the conductive elastic member 300 is not limited to this, and the movement direction may be determined based on the type of the battery cell and the manner in which the battery cell is placed in the checking area.

In one embodiment, the conductive elastic member 300 may be disposed on both one side and another side of the casing.

In one embodiment, after contacting the conductive elastic member 300 with the battery casing, a voltage may be applied by the measuring unit 40, and the resistance value between the battery casing and the conductive elastic member may be measured. The insulation status of the battery casing can be determined based on this resistance value.

In one embodiment, the casing 120 may include a first insulating layer, a conductive layer, and a second insulating layer stacked together, and the conductive layer may be exposed on a side of the casing 120.

In one embodiment, the battery casing may comprise a first insulating layer, a conductive layer, and a second insulating layer stacked together. In this case, resistance value is measured between the conductive layer and the conductive elastic member.

In one embodiment, the conductive elastic member 300 may cover the entire surface of one side of the casing.

In one embodiment, voltage may be applied simultaneously to the conductive elastic member 300 disposed on each of the one surface and the other surface of the battery casing to check both surfaces simultaneously.

If the measured resistance value is high, the insulation of the battery casing can be judged to be normal; if the measured resistance value is low, the insulation of the pouch casing can be judged to be damaged.

According to one embodiment, since the checking is performed by contact between the conductive elastic member and the casing, the checking time is not long. Therefore, the battery under checking does not need to be stopped at the working unit, and the checking can proceed while the battery is moving. Consequently, battery checking can be performed while keeping pace with battery mass production speed.

Typically, the exposure of the conductor layer in the battery casing is checked manually using a magnifying glass. The method involves the operator placing the magnifying glass over a suspected damaged area; if a bright metallic color is observed, it is treated as defective. However, defining the bright metallic color is difficult, and relying on the operator's subjective judgment for defect determination can lead to reduced reliability. Furthermore, if the defect in the insulation layer is very small, the amount of light reflected may be insufficient for detection even with the magnifying glass. Additionally, manual checking by workers can significantly reduce productivity on high-speed mass production lines.

Another method involves using salty solution to determine conductor layer exposure. Salty solution is applied to the damaged insulation area, allowed to permeate to the inner side of the pouch casing, and then a probe is placed on the salty solution soaked area and the conductive part of the pouch casing to check the insulation resistance. If the insulation resistance falls below the specified value, the pouch casing is deemed damaged. However, the process of individually applying and draining salty solution at each suspected damage site cannot keep pace with mass production line speeds. Furthermore, since salty solution is applied only to areas suspected of damage, sections without visible damage may be missed during checking.

Furthermore, while methods using plasma exist to determine conductor layer exposure, these require a separate gas supply for plasma generation, increasing production costs. Additionally, depending on the shape of the nozzle from which the plasma is sprayed, there is a possibility of missed detection if the plasma does not reach the damaged area of the pouch casing.

In contrast, the battery checking apparatus and battery checking method according to one embodiment of the present disclosure can quickly and accurately check whether the battery casing is damaged.

### Example

A sample was prepared to verify the validity of the present disclosure.

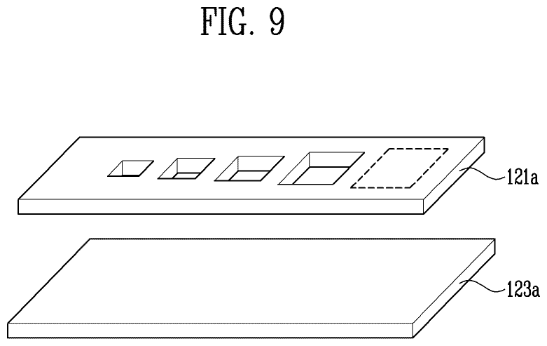

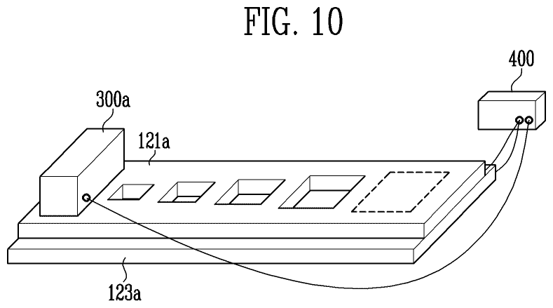

FIGS. 9 and 10 are schematic diagrams illustrating samples for validating the effectiveness of the present disclosure.

As shown in FIGS. 9 and 10, an insulating layer (121a, PET/Nylon) and an aluminum conductive layer 123a were laminated. At this time, defects of various sizes (1 mm, 1.5 mm, 2 mm, 3 mm, no defect) were introduced into the insulating layer (121a, PET/Nylon), and it was laminated onto the conductive layer 123a. Conductive rubber 300a was placed in contact with the insulating layer 121a. A first terminal was connected to the conductive layer 123a, and a second terminal was connected to the conductive rubber 300a. The conductive rubber 300a was placed over each defect to be tested, a voltage of 50V was applied while maintaining pressure, and the resistance was measured using a measuring instrument (HIOKI SM 7120). The results are shown in Table 1 below.

TABLE 1

| | 1 mm | 1.5 mm | 2 mm | 3 mm | No Defect |
|---|---|---|---|---|---|
| 1 | 1.07 | Over | Over | Over | 74.70 |
| 2 | 4.71 | Over | Over | Over | 108.09 |
| 3 | 3.88 | 0.24 | Over | Over | 254.21 |
| 4 | 0.22 | Over | Over | Over | 237.62 |
| 5 | 1.49 | Over | Over | Over | 104.89 |
| 6 | 2.51 | 1.18 | Over | Over | 212.41 |
| 7 | 0.13 | 5.73 | Over | Over | 125.21 |
| 8 | 0.06 | 2.61 | Over | Over | 129.80 |
| 9 | 0.39 | 0.92 | Over | Over | 243.96 |
| 10 | 0.52 | 0.20 | Over | Over | 74.83 |
| 11 | 0.30 | Over | Over | Over | 228.07 |
| 12 | 0.57 | 0.77 | Over | Over | 178.48 |
| 13 | 2.74 | Over | Over | Over | 137.90 |
| 14 | 1.55 | 1.04 | Over | Over | 149.62 |
| 15 | 0.54 | Over | Over | Over | 151.27 |
| 16 | 0.61 | 0.87 | Over | Over | 182.00 |
| 17 | Over | Over | Over | Over | 298.00 |
| 18 | 3.73 | Over | Over | Over | 251.00 |
| 19 | 0.51 | Over | Over | Over | 190.00 |
| 20 | 0.76 | Over | Over | Over | 151.00 |
| 21 | Over | 0.87 | Over | Over | 229.00 |
| 22 | 0.95 | Over | Over | Over | 227.00 |
| 23 | 0.43 | 1.06 | Over | Over | 200.00 |
| 24 | 0.57 | Over | Over | Over | 237.00 |
| 25 | 0.60 | Over | Over | Over | 100.00 |
| 26 | 2.00 | Over | Over | Over | 169.00 |
| 27 | 1.18 | Over | Over | Over | 176.00 |
| 28 | 1.01 | Over | Over | Over | 136.00 |
| 29 | 0.93 | Over | Over | Over | 262.00 |
| Average | 1.24 | 1.41 | Over | Over | 181.30 |

※ Over = Over Charge
※ Unit = MΩ

In Table 1 above, cases where the resistance is low and the current flowing when 50V is applied exceeds the current limit of the measuring instrument are marked as “over.” This indicates that the insulating layer is damaged, exposing the conductive layer, resulting in a high current flow.

For 2 mm and 3 mm defects, the low resistance value indicates poor insulation. Similarly, for 1 mm and 1.5 mm defects, the measured resistance is significantly lower than in the no-defect sample, also indicating poor insulation.

Despite the insulation layer 121a and conductive layer 123a not being fully bonded, and the conductive rubber 300a not being sufficiently compressed, the sample still yielded meaningful results.

To compare with the above sample, a pouch-type battery cell was fabricated and its resistance measured.

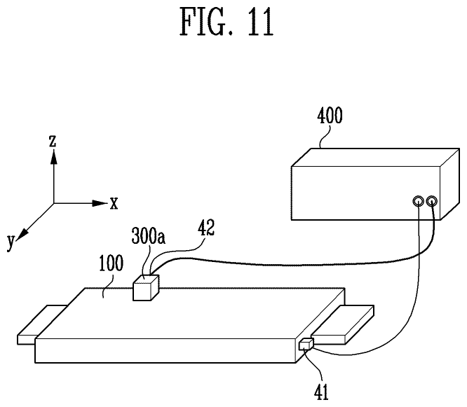

FIG. 11 is a schematic diagram illustrating a resistance value measurement method for a battery cell 100 according to one embodiment. A first terminal 41 was connected to the conductor layer exposed on the side of the pouch casing, conductive rubber 300a was pressed onto the top surface of the pouch casing, and a second terminal 42 was connected. A voltage of 50V was applied, and the resistance was measured using a measuring instrument (HIOKI SM 7120). Depending on the contact area of the conductive rubber, resistance values ranging from 150 to 236 Go were measured. This result is similar to the measurement level of the defect-free sample (No Defect) mentioned above.

The present disclosure may be practiced in various forms of modification and is not limited to the scope of the above-described embodiments. Therefore, if a modified embodiment includes the components of the claims of the present disclosure, it should be considered within the scope of the present disclosure.

What is claimed is:

1. An apparatus for checking battery, comprising:
a working unit that contacts a conductive elastic member to a casing of a battery to be checked; and
a measuring unit that applies a voltage between the casing and the conductive elastic member, measures a resistance value, and determines whether the casing is insulated based on the resistance value.

2. The apparatus for checking battery according to claim 1, wherein the working unit includes a work table and the conductive elastic member provided on the work table.

3. The apparatus for checking battery according to claim 1, further comprising:
a pressing unit including a pressing jig that presses the conductive elastic member and contacts the conductive elastic member to the casing.

4. The apparatus for checking battery according to claim 3, wherein the battery to be checked is moved in a horizontal direction, and the pressing jig moves from top to bottom to contact with the casing.

5. The apparatus for checking battery according to claim 1, wherein the conductive elastic member covers the entire surface of one side of the casing.

6. The apparatus for checking battery according to claim 1, wherein the measuring unit measures the resistance value and includes a resistance measuring device including first and second terminals electrically connected to the casing and the conductive elastic member.

7. The apparatus for checking battery according to claim 6, wherein the conductive elastic member is disposed on one side and another side of the casing, and the resistance measuring device further includes a third terminal, and the second terminal and the third terminal are electrically connected to a conductive rubber disposed on the one side and another side of the casing.

8. The apparatus for checking battery according to claim 1, wherein the battery to be checked is a pouch-type battery cell.

9. The apparatus for checking battery according to claim 1, wherein the casing includes a first insulating layer, a conductive layer, and a second insulating layer stacked together, and the conductive layer is exposed on a side of the casing.

10. The apparatus for checking battery according to claim 1, further comprising:
a transfer unit for transferring the battery to be checked to the working unit.

11. The apparatus for checking battery according to claim 1, wherein the battery to be checked is moved in the working unit with or without stopping for a predetermined period of time.

12. A checking method of battery comprising:
a step of contacting a conductive elastic member to a casing of a battery to be checked; and
a step of applying a voltage between the casing and the conductive elastic member, measuring a resistance value, and determining whether the casing is insulated based on the resistance value.

13. The checking method of battery according to claim 12, wherein the battery to be checked is moved in a horizontal direction, and the conductive elastic member moves from top to bottom to contact with the casing with a predetermined pressure.

14. The checking method of battery according to claim 12, wherein the casing includes a first insulating layer, a conductive layer, and a second insulating layer stacked together, and the resistance value is measured between the conductive layer and the conductive elastic member.

15. The checking method of battery according to claim 12, wherein the conductive elastic member covers the entire surface of one side of the casing.
